(19) United States
(12) Patent Application Publication
(10) Pub. No.: US 2023/0395579 A1
(43) Pub. Date: Dec. 7, 2023

(54) FLIP CHIP MICRODEVICE STRUCTURE

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 18/246,633

(22) PCT Filed: Oct. 19, 2021
(86) PCT No.: PCT/CA2021/051464

§ 371 Date: Mar. 24, 2023

Related U.S. Application Data
(60) Provisional application No. 63/093,502, filed on Oct. 19, 2020.

(51) Int. Cl. H01L 25/13; H01L 25/075; H01L 33/62; H01L 33/52

(52) U.S. Cl. CPC H01L 25/13; H01L 25/0753; H01L 33/62; H01L 33/52

(57) ABSTRACT

What is disclosed is structures and methods of integrating microdevices into a system substrate. In particular the structure comprises various components of buffer layer, release layer, pads, electrodes, VIA openings and various planarization layers and passivation layers. These components are configured to form an optoelectronic device or a system. Also described are methods to form an optoelectronic device.

### FIELD OF THE INVENTION

The present disclosure relates to the structure of flip chip or lateral microdevices into system substrate.

### BRIEF SUMMARY

According to one embodiment the invention relates to an optoelectronic system, the system comprising, microdevices transferred to a substrate, openings formed to provide access to the top of the microdevices, a second opening providing access to a common electrode and pads formed on top of openings coupling microdevices and the common electrode.

According to another embodiment the invention relates to a method to form an optoelectronic device, the method comprising, forming a release layer on a first substrate, transferring microdevices into the substrate using a bonding pad, forming a planarization layer and VIA openings to provide access to the top of microdevices and to the other side of a planarization layer, forming a common electrode to couple a top of the microdevice and the other side of the planarization layer through the VIA openings and bonding the optoelectronic device to another substrate.

According to another embodiment the invention relates to an optoelectronic system, the system comprising more than one pixel, each pixel having multiple microdevices and similar microdevices at two different pixels having a common line.

According to another embodiment the invention relates to an optoelectronic system, the system comprising more than one pixel, each pixel having multiple microdevices, a row connecting microdevices in a common line and a column connecting microdevices also has another common line.

### BRIEF DESCRIPTION OF THE DRAWINGS

The foregoing and other advantages of the disclosure will become apparent upon reading the following detailed description and upon reference to the drawings.

FIG. 1A shows an optoelectronic system where microdevices are transferred into a substrate.

FIG. 1B shows a common electrode that is transparent or patterned to provide a path for the light to emit.

FIG. 1C shows the exemplary cross section view of the optoelectronic system.

FIG. 1D shows another method of forming an optoelectronic device.

FIG. 1E shows another method of forming an optoelectronic device.

FIG. 1F and FIG. 1G, show the pads are coupled to the microdevices through other electrode contacts.

FIGS. 2A and 2B show more than one pixel is in a package.

The present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

A few embodiments of this description are related to integration of microdevices into a receiving substrate. The system substrate may comprise micro light emitting diodes (LEDs), Organic LEDs, sensors, solid state devices, integrated circuits, (micro-electro-mechanical systems) MEMS, and/or other electronic components.

The receiving substrate may be, but is not limited to, a printed circuit board (PCB), thin film transistor backplane, integrated circuit substrate, or, in one case of optical microdevices such as LEDs, a component of a display, for example a driving circuitry backplane. The patterning of microdevice donor substrate and receiving substrate can be used in combination with different transfer technology including but not limited to pick and place with different mechanisms (e.g. electrostatic transfer head, elastomer transfer head), or direct transfer mechanism such as dual function pads and more).

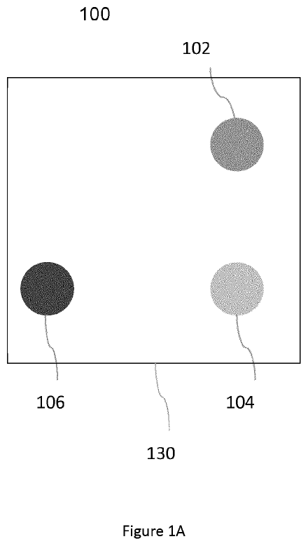

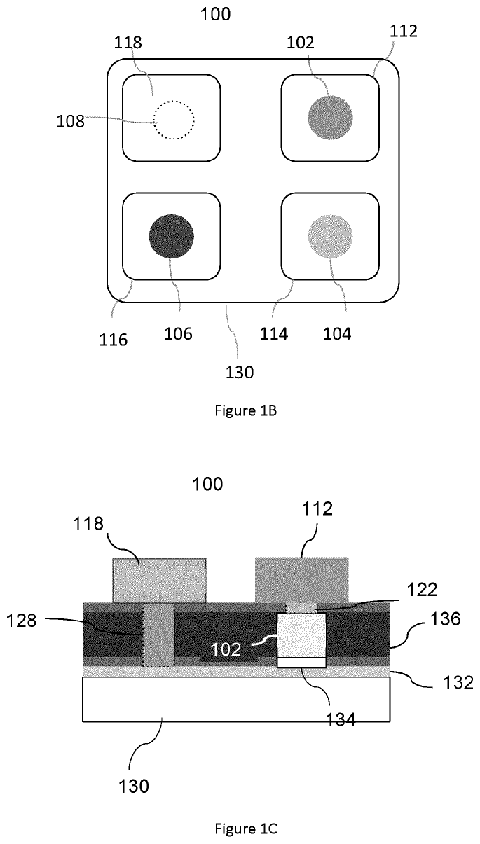

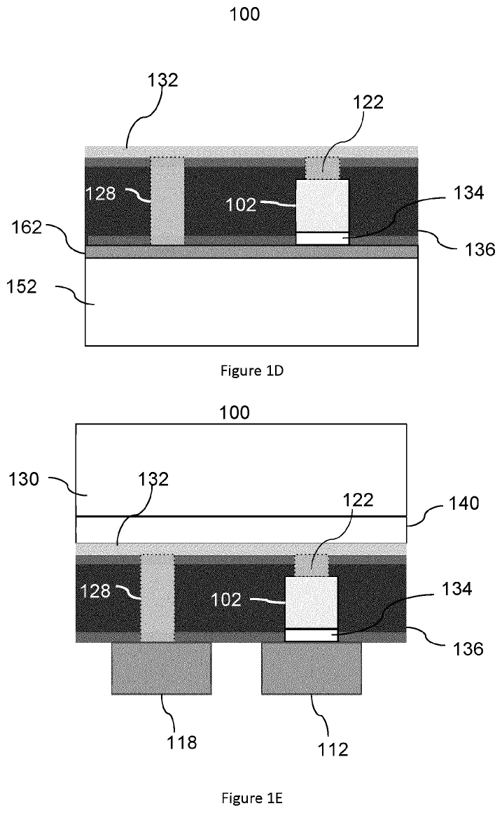

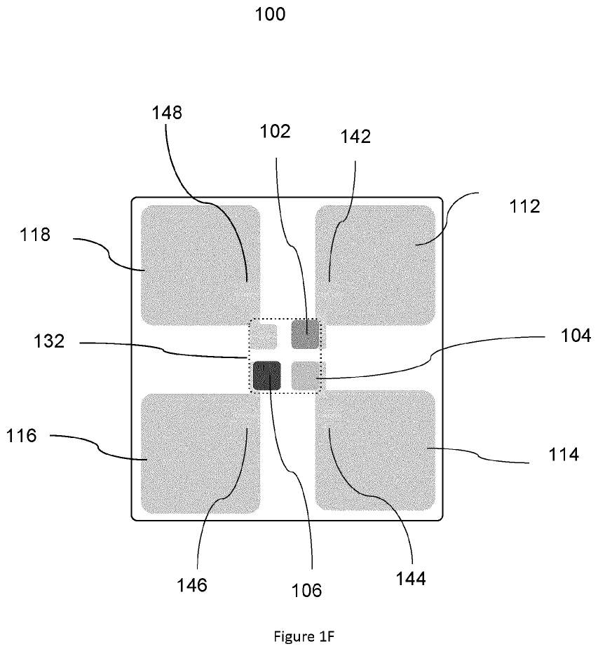

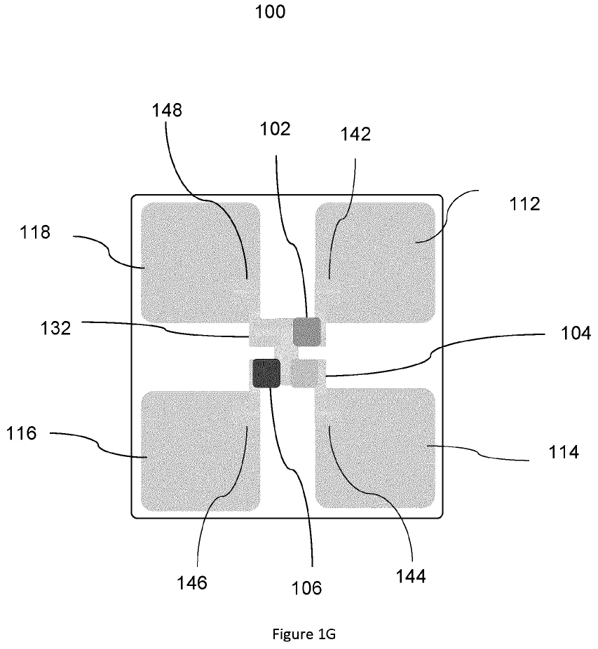

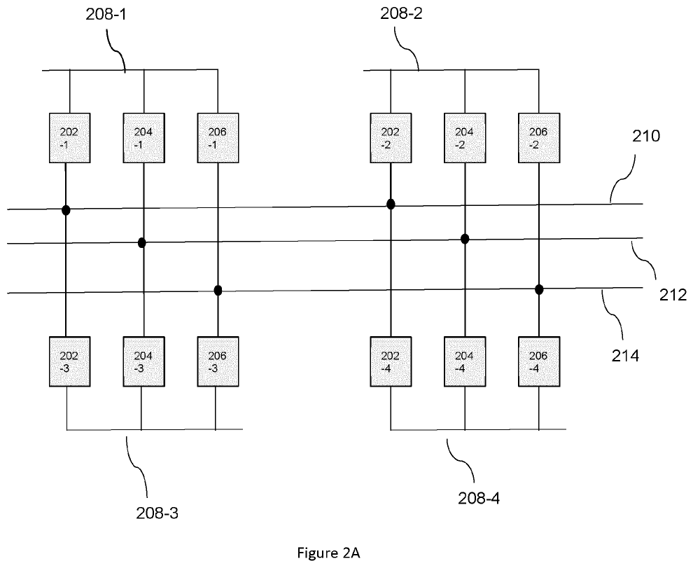

FIG. 1A shows an optoelectronic system 100 where microdevices 102, 104, and 106 are transferred into a substrate 130. A planarization or dielectric layer can be formed on top of the substrate 130. An opening can be formed to provide access to the top of the microdevices 102, 104, and 106. Also, FIG. 1B shows an opening 108 that provides access to a common electrode. Pads 112, 114, 116, and 118 can be formed on top of openings to couple to the microdevices 102, 104, and 106 and the common electrode.

With reference to FIG. 1B the common electrode can be transparent or patterned to provide a path for the light to emit.

FIG. 1C shows the exemplary cross section view of the optoelectronic system 100. A common electrode 132 is formed on top of the substrate 130. There can be buffer layers before the common electrode 132. Dielectric layers or other layers can form on top of the common electrode 132. An opening can form in the dielectric layers. A bonding pad 134 can couple to the common electrode 130. The microdevice 102 is on top of bonding pad 134. Planarization layer 136 is formed on top of the substrate. Opening 122 to the microdevice 102 and another opening 128 to provide access to the common electrode. Pads 118 and 112 form to provide access to the microdevice and common electrode 132. There can be openings and pads to other microdevices. The packaged optoelectronic system 100 can be bonded to another substrate to form a display or a sensor array using these bonds.

The optoelectronic device 100 in FIG. 1C and FIG. 1E includes a substrate 130, a common electrode 132, a microdevice coupled to the common electrode 132. The device 100 includes a planarization layer covering at least part of the device 136. There is an opening 128 in the planarization layer 132 to provide access to the common electrode 132. There is another opening 122 can form to provide access to the top of the microdevice 102. Pads 118 and 112 (116, 114) are formed to couple to the common electrode 132 and top of the microdevice 102.

In another method of forming an optoelectronic device 100, as shown in FIG. 1D, a release layer 162 is formed on a substrate 152. A microdevice 102 is transferred into the substrate 152. A bonding pad 134 can be used. A planarization layer 136 is formed and VIA openings 128 and 122 are formed to provide access to the top of microdevices and to the other side of the passivation layer 136. A common electrode 132 is formed to couple to the top of the microdevice 102 and the other side of the planarization layer through the openings 122, 128. The sample is bonded to another substrate 130. A bonding layer 140 (FIG. 1E) can be used to form a bond to the substrate 130. The substrate 152 is separated and pads 112 and 118 are formed to couple to the microdevice and the common electrode through VIA 128.

In FIG. 1F and FIG. 1G, another related embodiment, shows where the pads 112, 114, 116, and 118 are coupled to the microdevices through other electrode contacts 142, 144, 146, and 148.

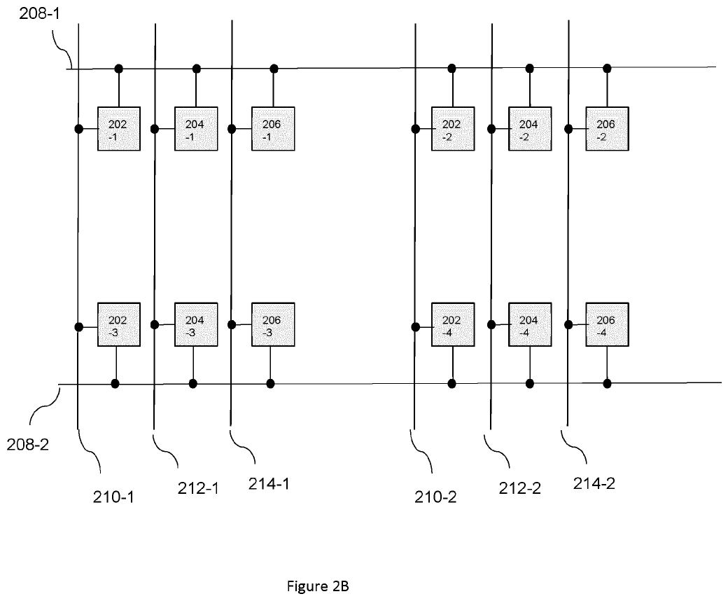

FIG. 2 (comprising of FIGS. 2A and 2B) shows more than one pixel is in a package or optoelectronic device/system. Here, each pixel has multiple devices (202-1, 202-2, 202-3, 202-4, 204-1, 204-2, 204-3, 204-4, 206-1, 206-2, 206-3, 206-4).

In FIG. 2A, the microdevices that are similar (or same) in at least two different pixels have a common line (210, 212, 214). This common line (210, 212, 214) can be a common select, a common activate, a common write or a common drive line. And the pixel has another control line. This control line (208-1, 208-2, 208-3, 208-4) can be either an activated, a select, a write, or a drive line. Here, select or active lines have two states. In one state, the devices connected to the select (write or activate) lines are off and cannot be ON. In another state, the devices connected to the select (active) lines can be turned on. In this case, the value of the devices are controlled by the data line (for example, the voltage or current in the data lines control the brightness of the devices). Here, either the microdevice in one pixel is activated first and the data is either being programmed or the microdevice is being driven or read. Then another pixel is activated and the microdevices in the second pixel are being either driven or read. In another case, the same microdevices of the first type in different pixels are activated first and then the said microdevices are being either driven or read. Then another type (second type) of microdevice is selected and the second type of microdevices are being driven or read.

In FIG. 2B, the row has a common line (208-1 208-2), the line can either be select line, drive line, write line, and etc. and the column also has the common line (210-1, 210-2, 212-1, 212-2, 214-1, 214-2) and the line can either be select line, drive line, write line, and etc. In one case, the column is activated first and the microdevices in that column are driven. Then the second column is activated first and then microdevices in that column are driven. In another case, the row is activated and the microdevices in that row are driven. Then the second row is activated and then the microdevices in that column are driven.

In another case, the combination of cases in FIGS. 2A and 2B can be used.

### Method Aspects

The invention discloses a method to form an optoelectronic device. The method comprises, forming a release layer on a first substrate; transferring microdevices into the substrate using a bonding pad, forming a planarization layer and VIA openings to provide access to the top of the microdevices and to the other side of the planarization layer, forming a common electrode to couple the top of the microdevice and the other side of the planarization layer through the VIA openings and bonding the optoelectronic device to another substrate.

Furthermore, a bonding layer is used to form a bond to the other substrate. Here, the first substrate is separated and pads are formed to couple to the microdevice and the common electrode through one of the VIA openings. Next, the optoelectronic system has pads that are coupled to the microdevices through other electrode contacts. The optoelectronic system comprises more than one pixel, and each pixel has multiple microdevices. Similar microdevices at two different pixels have a common line. The common line can be a common select, a common activate, a common write or a common drive line.

Next, wherein the pixel has a control line, the control line can be an active line, a select line, a white line or a drive line. If the microdevice in one pixel is activated first, the data is either being programmed or the microdevice is being driven or read. If a second pixel is activated, the microdevices in the second pixel are being either driven or read. Also, the same microdevices of the first type in different pixels are activated first which are then either driven or read. Similarly, a second type of microdevice is selected and then the second type of microdevices are driven or read.

In another embodiment, an optoelectronic system comprises more than one pixel, with each pixel having multiple microdevices. A row connecting microdevices is a common line and a column connecting microdevices also has another common line. Here, the common lines in the row and the columns are select lines, drive lines or write lines. Furthermore, a first column is activated and the microdevices in the first column are driven followed by a second column being activated and then microdevices in the second column are driven. Then, a first row is activated and the microdevices in the first row are driven followed by a second row being activated and then microdevices in the second row are driven.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. An optoelectronic system, the system comprising:
microdevices transferred to a substrate;
openings formed to provide access to the top of the microdevices;
a second opening providing access to a common electrode; and
pads formed on top of openings coupling microdevices and the common electrode.

2. The optoelectronic system of claim 1, wherein the common electrode is transparent or patterned.

3. The optoelectronic system of claim 1, wherein the common electrode is formed on top of the substrate.

4. The optoelectronic system of claim 3, wherein there are buffer layers before the common electrode.

5. The optoelectronic system of claim 3, wherein dielectric layers form on top of the common electrode with an opening in the dielectric layers.

6. The optoelectronic system of claim 5, wherein a bonding pad is coupled to the common electrode.

7. The optoelectronic system of claim 6, wherein the microdevice is on top of the bonding pad.

8. The optoelectronic system of claim 7, wherein a third opening to the microdevice and a fourth opening provide access to the common electrode.

9. The optoelectronic system of claim 6, wherein a planarization layer is formed on top of the substrate.

10. The optoelectronic system of claim 8, wherein pads form on top of third and fourth openings to provide access to the microdevice and common electrode.

11. The optoelectronic system of claim 8, wherein there are additional openings and pads to other microdevices.

12. The optoelectronic system of claim 11, wherein the optoelectronic system is bonded to another substrate to form a display or a sensor array.

13. The optoelectronic system of claim 8, wherein a planarization covers at least part of an optoelectronic device.

14. The optoelectronic system of claim 13, wherein the planarization layer has an opening to provide access to the common electrode and an additional opening to provide access to the top of the microdevice.

15. The optoelectronic system of claim 14, wherein pads are formed to couple to the top of the microdevice and the common electrode.

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. An optoelectronic system, the system comprising:
more than one pixel;
each pixel having multiple microdevices; and
wherein a row connecting microdevices is a common line and a column connecting microdevices also has another common line.

29. The system of claim 28, wherein the common lines in the row and the columns are select lines, drive lines or write lines.

30. The system of claim 29, firstly a first column is activated and the microdevices in the first column are driven followed by a second column being activated and then microdevices in the second column are driven.

31. The system of claim 29, firstly a first row is activated and the microdevices in the first row are driven followed by a second row being activated and then microdevices in the second row are driven.
